(19) United States
(12) Patent Application Publication
(10) Pub. No.: US 2016/0018684 A1
(43) Pub. Date: Jan. 21, 2016

(54) SUBSTRATE, DISPLAY DEVICE, AND METHOD FOR MANUFACTURING ALIGNMENT FILM

(71) Applicant: SHENZHEN CHINA STAR OPTOELECTRONICS TECHNOLOGY CO. LTD., Shenzhen, (CN)

(72) Inventor: Caiqin CHEN, Shenzhen (CN)

(21) Appl. No.: 14/416,386

(22) PCT Filed: Dec. 11, 2014
(86) PCT No.: PCT/CN2014/093527

§ 371 Date: Aug. 20, 2015

(30) Foreign Application Priority Data
Jul. 21, 2014 (CN) 201410348811.0

(51) Int. Cl. G02F 1/1337; B05D 1/02; H01L 27/12; G02F 1/1335; G02F 1/1368

(52) U.S. Cl. CPC G02F 1/1337; G02F 1/133512; G02F 1/1368; H01L 27/1214; B05D 1/02; G02F 2001/133397

(57) ABSTRACT

In the technical field of display, a substrate, a display device and a method for manufacturing an alignment film are disclosed. The present disclosure can solve the technical problem of image sticking of the liquid crystal display caused by the difference of feedthrough at different locations of the liquid crystal display device. The substrate of the present disclosure comprises a glass base and an alignment film formed on the glass base. The thickness of the alignment film measured along a lateral direction gradually becomes thinner from both ends of the alignment film to the center thereof, and/or the thickness of the alignment film measured along a longitudinal direction gradually becomes thinner from one end of the alignment film to the other end thereof. The present disclosure can be applied to display devices, such as liquid crystal television, liquid crystal display, mobile phone, and PC tablet, etc.

The present application claims benefit of Chinese patent application CN 201410348811.0, entitled “SUBSTRATE, DISPLAY DEVICE, AND METHOD FOR MANUFACTURING ALIGNMENT FILM” and filed on Jul. 21, 2014, which is incorporated herein by reference.

### TECHNICAL FIELD

The present disclosure relates to the technical field of display, and in particular, to a substrate, a display device, and a method for manufacturing an alignment film.

### TECHNICAL BACKGROUND

As display technology develops, a planar substrate has been commonly used in liquid crystal display device.

In a liquid crystal display device having various display modes, image sticking would more or less occur. That is, when changing a static picture after it is displayed over a prolonged period of time, a ghost image from the previous picture would be left behind. A main reason for image sticking is the difference of feedthrough at different locations of the liquid crystal display device, i.e., voltage drops produced by the driving signal at different locations of the display device are different.

Taking a bi-directional driven liquid crystal display device as an example, gate driving signal is inputted into the liquid crystal panel from both ends thereof. Due to the resistance of the gate line, delay of the gate driving signal would occur during its transmission along the gate line, and thus measured along a lateral direction, the feedthroughs at both ends of the liquid crystal panel would be higher than that at the center thereof. In contrast, a data signal is inputted into the liquid crystal panel from one end thereof. Due to the resistance of the data line, delay of the data signal would occur during its transmission along the data line, and thus measured along a longitudinal direction, the feedthrough near the end from which the data signal is inputted would be higher than that at locations away from the same end. Difference of feedthrough at different locations of the liquid crystal display device causes the technical problem of image sticking.

### SUMMARY OF THE INVENTION

The objective of the present disclosure is to provide a substrate, a display device, and a method for manufacturing an alignment film, so as to solve the technical problem of image sticking of the liquid crystal display device due to different feedthroughs at different locations of the liquid crystal display device.

The present disclosure provides a substrate, comprising a glass base, and an alignment film formed on the glass base,

wherein the thickness of the alignment film measured along a lateral direction gradually becomes thinner from both ends of the alignment film to the center thereof, and/or

the thickness of the alignment film measured along a longitudinal direction gradually becomes thinner from one end of the alignment film to the other end thereof.

Optionally, the substrate is an array substrate, and the substrate further comprises a thin film transistor and a pixel electrode disposed between the glass base and the alignment film.

Alternatively, the substrate is a color filter substrate, and the substrate further comprises a color filter layer and a common electrode disposed between the glass base and the alignment film.

The present disclosure further provides a display device, comprising the array substrate and/or the color filter substrate.

The present disclosure further provides a method for manufacturing an alignment film, comprising spray coating polyimide onto a glass base using a spraying plate,

wherein during spray coating polyimide onto the glass base with the spraying plate, the spraying plate moves along a lateral direction, and the rate of movement of the spraying plate gradually increases during its movement from one end of the glass base to the center thereof, but gradually decreases during its movement from the center of the glass base to the other end thereof,

and/or a plurality of nozzles are arranged on the spraying plate along a longitudinal direction thereof, and the spraying pressures of the nozzles are set to gradually decrease from the nozzles located at one end of the spraying plate to those located at the other end thereof.

The present disclosure further provides a method for manufacturing an alignment film, comprising spray coating polyimide onto the glass base using a spraying plate,

wherein during spray coating polyimide onto the glass base with the spraying plate, the spraying plate moves along a longitudinal direction, and the rate of movement of the spraying plate gradually decreases during its movement from one end of the glass base to the other end thereof,

and/or, a plurality of nozzles are arranged on the spraying plate along a lateral direction thereof, and the spraying pressures of the nozzles are set to gradually decrease from the nozzles located at both ends of the spraying plate to those located at the center thereof.

The present disclosure further provides another substrate, comprising a glass base, and an alignment film formed on the glass base, wherein the thickness of the alignment film measured along a lateral direction and/or a longitudinal direction gradually becomes thinner from one end of the alignment film to the other end thereof.

Optionally, the substrate is an array substrate, and the substrate further comprises a thin film transistor and a pixel electrode disposed between the glass base and the alignment film.

Alternatively, the substrate is a color filter substrate, and the substrate further comprises a color filter layer and a common electrode disposed between the glass base and the alignment film.

The present disclosure further provides a display device comprising the array substrate, and/or the color filter substrate.

The present disclosure further provides a method for manufacturing an alignment film, comprising spray coating polyimide onto a glass base using a spraying plate,

wherein during spray coating polyimide onto the glass base with the spraying plate, the spraying plate moves along a lateral direction or a longitudinal direction, the rate of movement of the spraying plate gradually decreases during its movement from one end of the glass base to the other end thereof,

and/or a plurality of nozzles are arranged on the spraying plate along a longitudinal direction or a lateral direction thereof, and the spraying pressures of the nozzles are set to gradually decrease from the nozzles located at one end of the spraying plate to those located at the other end thereof.

The present disclosure has the following beneficial effects. According to the technical solution of the present disclosure, in a bi-directional driven liquid crystal display device, the thickness of the alignment film, measured along a lateral direction, gradually becomes thinner from both ends of the alignment film to the center thereof. Therefore, in a liquid crystal panel formed with the substrate according to the present disclosure, the thickness of the liquid crystal layer would gradually become thicker from both ends of the liquid crystal panel to the center thereof. The thicker the liquid crystal layer, the smaller the dielectric constant of the equivalent capacitance formed between the common electrode and the pixel electrode, and thus, the equivalent capacitance of the liquid crystal panel gradually becomes smaller from both ends of the liquid crystal panel to the center thereof. The feedthrough is inversely proportional to the equivalent capacitance. Therefore, the feedthrough of the liquid crystal panel gradually becomes larger from both ends of the liquid crystal panel to the center thereof. In this manner, the phenomenon that the feedthrough measured along a lateral direction gradually becomes smaller from both ends of the liquid crystal panel to the center thereof due to the resistance of the gate line can be compensated. In this case, the feedthrough over different locations of the liquid crystal display device can be more uniform, thereby the technical problem of image sticking of the liquid crystal display device can be solved.

In a unidirectional driven liquid crystal display device, the thickness of the alignment film, measured along a lateral direction, gradually becomes thinner from one end of the alignment film to the other end thereof. Thus, in a liquid crystal panel formed with this substrate, the relatively thick end of the alignment film can be arranged to correspond to an input end of a gate, so that the thickness of the liquid crystal layer can gradually become larger from the input end of the gate to an end away from the input end thereof. In this case, the dielectric constant of the equivalent capacitance can gradually become smaller, and so does the equivalent capacitance, thereby the feedthrough of the liquid crystal panel can gradually become larger from the input end of the gate to the end away from the input end thereof. In this manner, the phenomenon that the feedthrough of the liquid crystal panel gradually becomes smaller from the input end of the gate to the end away from the input end thereof due to the resistance of the gate line can be compensated. As a result, the feedthroughs over different locations on the liquid crystal display device can be more uniform, and thus the technical problem of image sticking of the liquid crystal display device can be solved.

On the other hand, the thickness of the alignment film on the substrate, measured along a longitudinal direction, gradually decreases from one end of the alignment film to the other end thereof. Thus, in a liquid crystal panel formed with this substrate, the relatively thick end of the alignment film can be arranged to correspond to the data input end, so that the thickness of the liquid crystal layer can gradually become larger from the data input end to the other end away from the data input end. In this case, the dielectric constant of the equivalent capacitance can gradually become smaller, and so does the equivalent capacitance, thereby the feedthrough of the liquid crystal panel can gradually become larger from the data input end to the end away from the data input end. In this manner, the phenomenon that the feedthrough of the liquid crystal panel gradually becomes smaller from the data input end to the end away from the data input end due to the resistance of the data line can be compensated. As a result, the feedthroughs over different locations on the liquid crystal display device can be more uniform, and thus the technical problem of image sticking of the liquid crystal display device can be solved.

Other features and advantages of the present disclosure will be further explained in the following description, and are partially become more readily evident therefrom, or be understood through implementing the present disclosure. The objectives and advantages of the present disclosure will be achieved through the structure specifically pointed out in the description, claims, and the accompanying drawings.

### BRIEF DESCRIPTION OF THE ACCOMPANYING DRAWINGS

In order to illustrate the technical solutions of the examples of the present disclosure more clearly, the accompanying drawings needed for describing the examples will be explained briefly. In the drawings:

FIG. 1 schematically shows a lateral cross-sectional view of a substrate according to example 1 of the present disclosure,

FIG. 2 schematically shows a longitudinal sectional view of the substrate according to example 1 of the present disclosure,

FIG. 3 schematically shows a lateral cross-sectional view of a display device according to example 1 of the present disclosure, and

FIG. 4 schematically shows a longitudinal sectional view of the display device according to example 1 of the present disclosure.

### DETAILED DESCRIPTION OF THE EMBODIMENTS

The present disclosure will be explained in detail with reference to the embodiments and the accompanying drawings, whereby it can be fully understood about how to solve the technical problem by the technical means according to the present disclosure and achieve the technical effects thereof, and thus the technical solution according to the present disclosure can be implemented. It is important to note that as long as there is no structural conflict, various embodiments as well as the respective technical features mentioned herein may be combined with one another in any manner, and the technical solutions obtained all fall within the scope of the present disclosure.

### Example 1

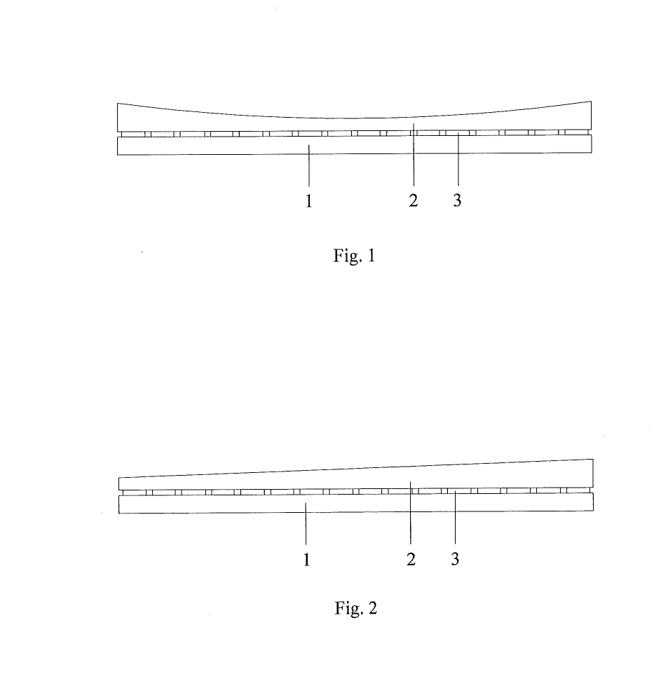

The substrate provided by the present example can be an array substrate, or a color filter substrate. As shown in FIG. 1, the present example is illustrated with an array substrate. The array substrate comprises a glass base 1, and an alignment film 2 formed on the glass base 1. The array substrate further comprises a thin film transistor (not shown) and a pixel electrode 3 disposed between the glass base 1 and the alignment film 2. If the substrate is embodied as a color filter substrate, a color filter layer and a common electrode are arranged between the glass base and the alignment film.

The array substrate provided by the present example can be used in a bi-directional driven liquid crystal display device. The thickness of the alignment film 2 in the array substrate, measured along a lateral direction, gradually becomes thinner from both ends of the alignment film 2 to the center thereof. Therefore, in a liquid crystal panel formed with this array substrate, the thickness of the liquid crystal layer would gradually become thicker from both ends of the liquid crystal panel to the center thereof. The thicker the liquid crystal layer, the smaller the dielectric constant of the equivalent capacitance formed between the common electrode and the pixel electrode 3, and thus the equivalent capacitance of the liquid crystal panel gradually becomes smaller from both ends of the liquid crystal panel to the center thereof. The feedthrough can be represented as feedthrough=(Vgh−Vgl)Cgs/(Clc+Cst+Cgs), wherein Vgh and Vgl respectively refer to a high level input and a low level input of the gate incoming signal, Cgs refers to a parasitic capacitance, Clc refers to the equivalent capacitance, and Cst refers to a storage capacitance. Thus, the feedthrough is inversely proportional to the equivalent capacitance Clc. Therefore, the feedthrough of the liquid crystal panel gradually becomes larger from both ends of the liquid crystal panel to the center thereof. In this manner, the phenomenon that the feedthrough measured along a lateral direction gradually becomes smaller from both ends of the liquid crystal panel to the center thereof due to the resistance of the gate line can be compensated. In this case, the feedthrough over different locations of the liquid crystal display device can be more uniform, thereby the technical problem of image sticking of the liquid crystal display device can be solved.

On another aspect, as shown in FIG. 2, in the array substrate according to the example of the present disclosure, the thickness of the alignment film 2, measured along a longitudinal direction, gradually becomes thinner from one end of the alignment film 2 to the other end thereof. Thus, in a liquid crystal panel formed with this array substrate, the relatively thick end of the alignment film 2 can be arranged to correspond to the data input end, so that the thickness of the liquid crystal layer can gradually become larger from the data input end to the other end away from the data input end. In this case, the dielectric constant of the equivalent capacitance can gradually become smaller, and so does the equivalent capacitance. According to the equation of feedthrough=(Vgh−Vgl)Cgs/(Clc+Cst+Cgs), the feedthrough is inversely proportional to the equivalent capacitance Clc, thereby the feedthrough of the liquid crystal panel can gradually become larger from the data input end to the end away from the data input end. In this manner, the phenomenon that the feedthrough of the liquid crystal panel gradually becomes smaller from the data input end to the end away from the data input end due to the resistance of the data line can be compensated. As a result, the feedthroughs over different locations on the liquid crystal display device can be more uniform, and thus the technical problem of image sticking of the liquid crystal display device can be solved.

In other examples, in the array substrate or the color filter substrate, the thickness of the alignment film can gradually becomes thinner from both ends of the alignment film to the center thereof only when measured along the lateral direction, but that of the alignment film measured along the longitudinal direction is the same. Alternatively, the thickness of the alignment film can gradually becomes thinner from one end of the alignment film to the other end thereof only when measured along the longitudinal direction, and that of the alignment film measured along the lateral direction is the same.

The example of the present disclosure provides a method for manufacturing an alignment film in the array substrate or color filter substrate, comprising spray coating polyimide (PI) onto a glass base using a spraying plate.

During spray coating PI onto the glass base with the spraying plate, the spraying plate moves along a lateral direction, and the rate of movement of the spraying plate gradually increases during its movement from one end of the glass base to the center thereof, so that the thickness of the PI sprayed onto the glass base through the spraying plate gradually becomes thinner from this end of the glass base to the center thereof. By contrast, the rate of movement of the spraying plate gradually decreases during its movement from the center of the glass base to the other end thereof, so that the thickness of the PI sprayed onto the glass base through the spraying plate gradually becomes thicker from the center of the glass base to the other end thereof. As a result, after subsequent steps, such as heating the PI, an alignment film having a thickness gradually becoming thinner from both ends of the alignment film to the center thereof can be formed.

On another aspect, a plurality of nozzles are arranged on the spraying plate along a longitudinal direction thereof, and the spraying pressures of the nozzles are set to gradually decrease from the nozzles located at one end of the spraying plate to those located at the other end thereof. The larger the spraying pressure, the thicker the PI sprayed by the nozzle. In this case, the thickness of the PI formed on the glass base can gradually become thinner from one end of the glass base to the other end thereof. As a result, after subsequent steps, such as heating the PI, an alignment film having a thickness gradually becoming thinner from one end of the alignment film to the other end thereof can be formed.

In other examples, if the thickness of the alignment film gradually becomes thinner from both ends of the alignment film to the center thereof only when measured along the lateral direction but that of the alignment film measured along the longitudinal direction is the same, it is necessary to control the rate of movement of the spraying plate only during the manufacturing of the alignment film, so that the rate of movement of the spraying plate gradually increases during its movement from one end of the glass base to the center thereof, but gradually decreases during its movement from the center of the glass base to the other end thereof, with the spraying pressure of each of the nozzles being the same. If the thickness of the alignment film gradually becomes thinner from one end of the alignment film to the other end thereof only when measured along the longitudinal direction but that of the alignment film measured along the lateral direction is the same, it is necessary to enable the spraying pressures of the nozzles to gradually decrease only during the manufacturing of the alignment film, with the rate of movement of the spraying plate remaining constant.

The example of the present disclosure further provides a method for manufacturing the alignment film, comprising spray coating polyimide (PI) onto a glass base using a spraying plate.

During spray coating PI onto the glass base with the spraying plate, the spraying plate moves along a longitudinal direction, and the rate of movement of the spraying plate gradually decreases during its movement from one end of the glass base to the other end thereof, so that the thickness of PI sprayed onto the glass base through the spraying plate gradually becomes thicker from one end of the glass base to the other end thereof. As a result, after subsequent steps, such as heating the PI, an alignment film having a thickness gradually becoming thicker from one end of the alignment film to the other end thereof can be formed.

On another aspect, a plurality of nozzles are arranged on the spraying plate along a lateral direction thereof, and the spraying pressures of the nozzles are set to gradually decrease from the nozzles located at both ends of the spraying plate to those located at the center thereof, so that the thickness of PI formed on the glass base can gradually become thinner from both ends of the glass base to the center thereof. As a result, after subsequent steps, such as heating the PI, an alignment film having a thickness gradually becoming thinner from both ends of the alignment film to the center thereof can be formed.

In other examples, if the thickness of the alignment film gradually becomes thinner from both ends of the alignment film to the center thereof only when measured along the lateral direction but that of the alignment film measured along the longitudinal direction is the same, it is necessary to control the spraying pressures of the nozzles to decrease from the nozzles located at both ends of the spraying plate to those located at the center thereof only during the manufacturing of the alignment film, with the rate of movement of the spraying plate remaining constant. If the thickness of the alignment film gradually becomes thinner from one end of the alignment film to the other end thereof only when measured along the longitudinal direction but that of the alignment film measured along a lateral direction is the same, it is necessary to control the rate of movement of the spraying plate only during the manufacturing of the alignment film, so that the rate of movement of the spraying plate gradually increases during its movement from one end of the glass base to the other end thereof, with the spraying pressure of each of the nozzles on the spraying plate being the same.

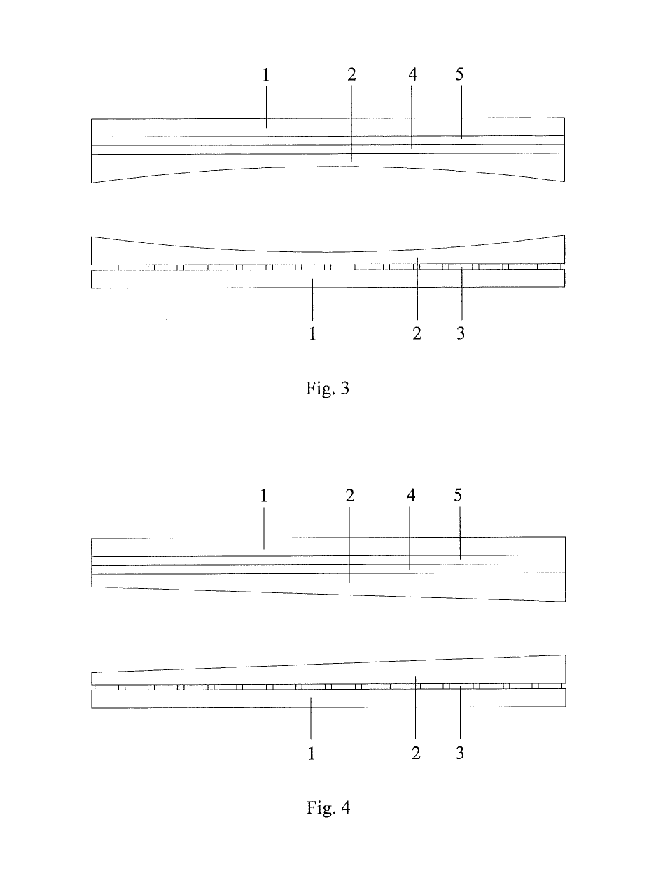

The example of the present disclosure further provides a display device comprising the array substrate and the color filter substrate as mentioned above. As shown in FIG. 3, the array substrate comprises a glass base 1, an alignment film 2, and a pixel electrode 3 disposed between the glass base 1 and the alignment film 2. The color filter substrate comprises a glass base 1, an alignment film 2, and a common electrode 4 and a color filter layer 5 disposed between the glass base 1 and the alignment film 2.

In the display device, the thickness of the alignment film 2 on each of the array substrate and the color filter substrate, measured along a lateral direction, gradually becomes thinner from both ends of the alignment film 2 to the center thereof, and thus the thickness of the liquid crystal layer in the display device gradually becomes thicker from both ends of the display device to the center thereof, thereby the dielectric constant of the equivalent capacitance formed between the pixel electrode 3 and the common electrode gradually becomes smaller. As a result, the equivalent capacitance of the display device gradually becomes smaller from both ends of the display device to the center thereof. According to the equation of Feedthrough=(Vgh−Vgl) Cgs/(Clc+Cst+Cgs), the feedthrough is inversely proportional to the equivalent capacitance Clc, thereby the feedthrough of the display device gradually becomes larger from both ends of the display device to the center thereof. In this manner, the phenomenon that the feedthrough of the liquid crystal panel measured along a lateral direction gradually becomes smaller from both ends of the display device to the center thereof due to the resistance of the gate line can be compensated. As a result, the feedthroughs over different locations on the liquid crystal display device can be more uniform, and thus the technical problem of image sticking of the liquid crystal display device can be solved.

On another aspect, as shown in FIG. 4, the thickness of the alignment film 2 on each of the array substrate and the color filter substrate, measured along a longitudinal direction, gradually becomes thinner from one end of the alignment film 2 to the other end thereof. Thus, in this display device, the relatively thick end of the alignment film 2 can be arranged to correspond to the data input end, so that the thickness of the liquid crystal layer can gradually become larger from the data input end to the other end away from the data input end. In this case, the dielectric constant of the equivalent capacitance formed between the pixel electrode 3 and the common electrode 4 can gradually become smaller, and thus the equivalent capacitance gradually becomes smaller from the data input end to the other end away from the data input end. According to the equation of Feedthrough=(Vgh−Vgl) Cgs/(Clc+Cst+Cgs), the feedthrough is inversely proportional to the equivalent capacitance Clc, thereby the feedthrough of the display device can gradually become larger from the data input end to the other end away from the data input end. In this manner, the phenomenon that the feedthrough of the display device gradually becomes smaller from the data input end to the end away from the data input end due to the resistance of the data line can be compensated. As a result, the feedthroughs over different locations on the liquid crystal display device can be more uniform, and thus the technical problem of image sticking of the liquid crystal display device can be solved.

In other examples, the display device can also use the abovementioned array substrate only (or the color filter substrate only), and the thickness throughout the alignment film on the color filter substrate (or array substrate) thereof is the same. In this manner, the technical problem of image sticking can also be solved.

### Example 2

Example 2 is substantially the same as example 1. The difference of example 2 from example 1 is that the substrate according to this example can be used in a unidirectional driven liquid crystal display device. The substrate can be an array substrate comprising a glass base, an alignment film, and a thin film transistor and a pixel electrode disposed between the glass base and the alignment film, etc. The substrate can also be a color filter substrate comprising a glass base, an alignment film, and a color filter layer and a common electrode disposed between the glass base and the alignment film, etc.

The array substrate or color filter substrate according to this example is different from that of example 1 in that the thickness of the alignment film thereof measured along a lateral direction gradually becomes thinner from one end of the alignment film to the other end thereof. Thus, in a unidirectional driven liquid crystal panel formed with this array substrate or color filter substrate, the relatively thick end of the alignment film can be arranged to correspond to an input end of a gate, so that the thickness of the liquid crystal layer can gradually become larger from the input end of the gate to an end away from the input end thereof. In this case, the dielectric constant of the equivalent capacitance can gradually become smaller, and so does the equivalent capacitance. According to the equation of Feedthrough=(Vgh−Vgl)Cgs/(Clc+Cst+Cgs), the feedthrough is inversely proportional to the equivalent capacitance Clc, thereby the feedthrough of the liquid crystal panel can gradually become larger from the input end of the gate to the end away from the input end thereof. In this manner, the phenomenon that the feedthrough of the liquid crystal panel gradually becomes smaller from the input end of the gate to the end away from the input end thereof due to the resistance of the gate line can be compensated. As a result, the feedthroughs over different locations on the liquid crystal display device can be more uniform, and thus the technical problem of image sticking of the liquid crystal display device can be solved.

The example of the present disclosure further provides a method for manufacturing the alignment film of said array substrate or color filter substrate, comprising spray coating polyimide (PI) onto a glass base using a spraying plate.

During spray coating polyimide onto the glass base with the spraying plate, the spraying plate moves along a lateral direction (or a longitudinal direction), and the rate of movement of the spraying plate gradually decreases during its movement from one end of the glass base to the other end thereof, so that the thickness of the PI sprayed onto the glass base through the spraying plate gradually becomes larger from one end of the glass base to the other end thereof. As a result, after subsequent steps, such as heating the PI, an alignment film having a thickness gradually becoming larger from one end of the alignment film to the other end thereof can be formed.

On another aspect, a plurality of nozzles are arranged on the spraying plate along a longitudinal direction (or a lateral direction) thereof, and the spraying pressures of the nozzles are set to gradually decrease from the nozzles located at one end of the spraying plate to those located at the other end thereof, so that the thickness of the PI sprayed onto the glass base through the spraying plate gradually becomes smaller from one end of the glass base to the other end thereof. As a result, after subsequent steps, such as heating the PI, an alignment film having a thickness gradually becoming thinner from one end of the alignment film to the other end thereof can be formed.

In other examples, if the thickness of the alignment film gradually becomes thinner from one end of the alignment film to the other end thereof only when measured along a lateral direction (or a longitudinal direction), but that of the alignment film measured along the longitudinal direction (or the lateral direction) is the same, it is necessary to control the rate of movement of the spraying plate only during the manufacturing of the alignment film, so that the rate of movement of the spraying plate gradually increases during its movement from one end of the glass base to the other end thereof, with the spraying pressure of each of the nozzles being the same. Alternatively, it is necessary to control the spraying pressures of the nozzles gradually to decrease from the nozzles located at one end of the spraying plate to those located at the other end thereof, with the rate of movement of the spraying plate remaining constant.

The example of the present disclosure further provides a display device comprising said array substrate and color filter substrate. Because the display device has the same technical features with said array substrate and color filter substrate, and thus it can achieve the same technical effects and solve the same technical problem.

The above embodiments are described only for better understanding, rather than restricting, the present disclosure. Any person skilled in the art can make amendments to the implementing forms or details without departing from the spirit and scope of the present disclosure. The scope of the present disclosure should still be subjected to the scope defined in the claims.

1. A substrate, comprising a glass base, and an alignment film formed on the glass base,
wherein the thickness of the alignment film measured along a lateral direction gradually becomes thinner from both ends of the alignment film to the center thereof, or becomes thinner from one end of the alignment film to the other end thereof, and/or
the thickness of the alignment film measured along a longitudinal direction gradually becomes thinner from one end of the alignment film to the other end thereof.

2. The substrate according to claim 1, wherein the substrate is an array substrate, and the substrate further comprises a thin film transistor and a pixel electrode disposed between the glass base and the alignment film.

3. The substrate according to claim 1, wherein the substrate is a color filter substrate, and the substrate further comprises a color filter layer and a common electrode disposed between the glass base and the alignment film.

4. A display device comprising a substrate, wherein the substrate comprises a glass base, and an alignment film formed on the glass base,
the thickness of the alignment film measured along a lateral direction gradually becomes thinner from both ends of the alignment film to the center thereof, or becomes thinner from one end of the alignment film to the other end thereof
and/or, the thickness of the alignment film measured along a longitudinal direction gradually becomes thinner from one end of the alignment film to the other end thereof.

5. The display device according to claim 4, wherein the substrate is an array substrate,
and the substrate further comprises a thin film transistor and a pixel electrode disposed between the glass base and the alignment film.

6. The display device according to claim 4, wherein the substrate is a color filter substrate,
and the substrate further comprises a color filter layer and a common electrode disposed between the glass base and the alignment film.

7. A method for manufacturing an alignment film, comprising spray coating polyimide onto a glass base using a spraying plate,
wherein during spray coating polyimide onto the glass base with the spraying plate,
the spraying plate moves along a lateral direction, and the rate of movement of the spraying plate gradually increases during its movement from one end of the glass base to the center thereof, but gradually decreases during its movement from the center of the glass base to the other end thereof, and/or, a plurality of nozzles are arranged on the spraying plate along a longitudinal direction thereof, and the spraying pressures of the nozzles are set to gradually decrease from the nozzles located at one end of the spraying plate to those located at the other end thereof;
or, the spraying plate moves along a longitudinal direction, and the rate of movement of the spraying plate gradually decreases during its movement from one end of the glass base to the other end thereof, and/or, a plurality of nozzles are arranged on the spraying plate along a lateral direction thereof, and the spraying pressures of the nozzles are set to gradually decrease from the nozzles located at both ends of the spraying plate to those located at the center thereof;
or, the spraying plate moves along a lateral direction or a longitudinal direction, and the rate of movement of the spraying plate gradually decreases during its movement from one end of the glass base to the other end thereof, and/or, a plurality of nozzles are arranged on the spraying plate along a longitudinal direction or a lateral direction thereof, and the spraying pressures of the nozzles are set to gradually decrease from the nozzles located at one end of the spraying plate to those located at the other end thereof.
